(19) United States
(12) Patent Application Publication
(10) Pub. No.: US 2017/0207303 A1
(43) Pub. Date: Jul. 20, 2017

(54) SEMICONDUCTOR MULTILAYER STRUCTURE

(71) Applicant: Hermes-Epitek Corp., Taipei City (TW)

(72) Inventor: Po-Jung LIN, HSINCHU (TW)

(21) Appl. No.: 15/477,598

(22) Filed: Apr. 3, 2017

Related U.S. Application Data
(63) Continuation-in-part of application No. 14/678,475, filed on Apr. 3, 2015, now abandoned.

(51) Int. Cl. H01L 29/15; H01L 29/20; H01L 21/02; H01L 29/205

(52) U.S. Cl. CPC H01L 29/151; H01L 29/205; H01L 29/2003; H01L 21/02381; H01L 21/02458; H01L 21/0254; H01L 21/02507

(57) ABSTRACT

The present invention is directed to a semiconductor multilayer structure. A semiconductor multilayer structure comprises a silicon substrate, a buffer layer deposited on the silicon substrate, and the buffer layer is an aluminum contained nitride buffer layer; a superlattice layer deposited on the buffer layer, wherein the superlattice layer comprises at least a gallium nitride layer and at least a aluminum nitride layer stacked together in order, and a diffusion layer formed between the aluminum nitride layer and the gallium nitride layer, wherein the diffusion layer is an aluminum gallium nitride layer; and a epitaxy layer deposited on the superlattice layer. By utilizing the present invention, the lattice mismatch between MN and GaN of the superlattice layer can be reduced, and efficiently accumulated can be maintained without causing relaxation.

### CROSS-REFERENCE TO RELATED APPLICATION

This is a continuation-in-part of application Ser. No. 14/678,475, filed in Apr. 3, 2015.

### BACKGROUND OF THE INVENTION

1. Field of the Invention

The present invention relates to a semiconductor multilayer structure, and more particularly to a semiconductor multilayer structure for an optical device or an electronic device.

2. Description of the Prior Art

Currently, large size silicon wafers have become favored choice to fabricate light emitting diodes and high power devices. Comparing to sapphire substrate, the silicon substrate has advantages including: lower cost, better efficiency of heat dissipation and capability of larger size. However, it has disadvantages including higher lattice mismatch with GaN (it causes crack of GaN films when lowering temperature) and melt back etching effect. To overcome these drawbacks, AlN is usually used as buffer layers to reduce lattice mismatch between GaN and silicon and mitigate residue stress; it also can prevent melt back etching effect between Ga and silicon. In this regard, growing a AlN buffer layer with high quality and flatness has become an essential step before growing GaN epitaxial layers. Nevertheless, higher temperature is required to grow the AlN buffer layer; the equipment to grow GaN cannot satisfy the requirement. This will increase costs to purchase additional equipment and energy consumption. In an alternative design, as disclosed in U.S. published patent application Ser. No. US 2010/0243989A1, which published on Sep. 30, 2010, a buffer layer composed of two different AlGaN layers that are alternately stacked and have different aluminum compositions is disclosed.

In this consideration, a semiconductor multilayer structure should be developed to simplified the process and reduce costs.

### SUMMARY OF THE INVENTION

The present invention is directed to a semiconductor multilayer structure. By utilizing the indium-containing and/or gallium-containing catalyst, the aluminum (Al) migration can be enhanced to increase quality and flatness of the Al contained nitride buffer layer, the temperature of growing Al contained nitride buffer layer can be lowered and thermal defects can also be prevented. Additionally, the costs and energy consumption can be reduced; and the lattice mismatch between AlN and GaN of the superlattice layer can be reduced, and efficiently accumulated can be maintained without causing relaxation.

According to one embodiment of the present invention, a semiconductor multilayer structure comprising: a silicon substrate; a silicon substrate; a buffer layer deposited on the silicon substrate, and the buffer layer is an aluminum contained nitride buffer layer; a superlattice layer deposited on the buffer layer, wherein the superlattice layer comprises at least a aluminum nitride layer and at least a gallium nitride layer stacked together in order, and a diffusion layer formed between the aluminum nitride layer and the gallium nitride layer, wherein the diffusion layer is an aluminum gallium nitride layer; and a epitaxy layer deposited on the superlattice layer.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

The foregoing conceptions and their accompanying advantages of this invention will become more readily appreciated after being better understood by referring to the following detailed description, in conjunction with the accompanying drawings, wherein:

FIG. 1 is a flowchart illustrating the fabrication method of the semiconductor multilayer structure according to one embodiment of the present invention;

FIG. 2 is a schematic diagram illustrating the semiconductor multilayer structure according to another embodiment of the present invention;

FIG. 3 is a flowchart illustrating the fabrication method of the semiconductor multilayer structure according to one embodiment of the present invention;

FIG. 4 is a schematic diagram illustrating the semiconductor multilayer structure according to another embodiment of the present invention;

FIG. 5 is a schematic diagram illustrating the semiconductor multilayer structure according to another embodiment of the present invention;

FIG. 6 is a schematic diagram illustrating the semiconductor multilayer structure according to another embodiment of the present invention;

FIG. 7 is a schematic diagram illustrating the semiconductor multilayer structure according to another embodiment of the present invention;

FIG. 8 is a schematic diagram illustrating a partially enlarged structure of the FIG. 7; and

FIG. 9A and 9B are electron microscope images showing different partially enlarged views of the semiconductor multilayer structure of the FIG. 7.

### DESCRIPTION OF THE PREFERRED EMBODIMENT

The detailed explanation of the present invention is described as follows. The described preferred embodiments are presented for purposes of illustrations and description, and they are not intended to limit the scope of the present invention.

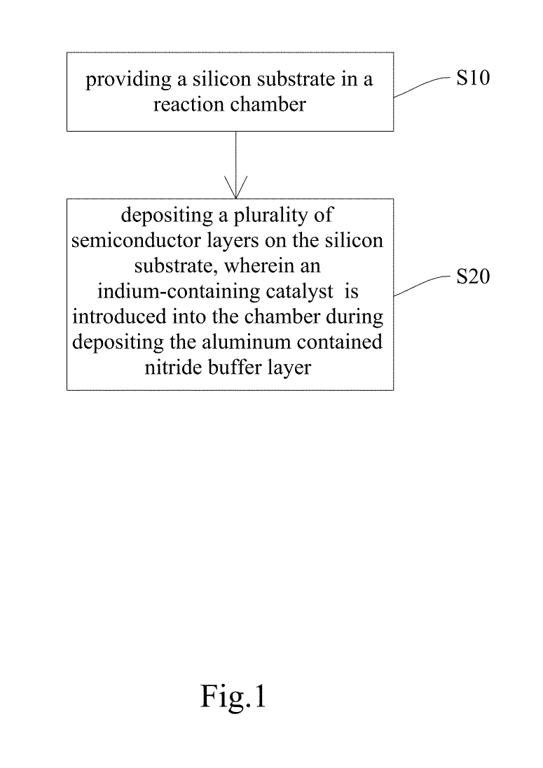

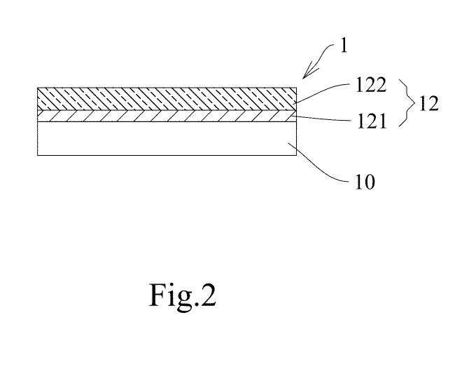

Referring to FIG. 1 and FIG. 2, wherein FIG. 1 is a flowchart illustrating the fabrication method of the semiconductor multilayer structure according to one embodiment of the present invention; and FIG. 2 is a schematic diagram illustrating the semiconductor multilayer structure according to one embodiment of the present invention. The fabrication method of a semiconductor multilayer structure 1 is described in the following. First, a silicon substrate 10 is provided in a reaction chamber (step S10). And then, a plurality of semiconductor layers 12 is deposited on the silicon substrate 10, wherein at least one of the semiconductor layers 12 is an aluminum contained nitride layer. An indium-containing catalyst is introduced into the chamber to enhance migration of aluminum in the aluminum contained nitride layer during depositing the aluminum contained nitride layer (step S20). In one embodiment, the aluminum contained nitride layer is a buffer layer 121 and the buffer layer 121 is depositing on the silicon substrate 10 directly. In one embodiment, the semiconductor layers 12 comprise an epitaxy layer 122 and the epitaxy layer 122 is depositing on the buffer layer 121, wherein the epitaxy layer 122 can be but not limited to the nitride epitaxy layer. The buffer layer is utilized to reduce the lattice mismatch between the epitaxy layer 122 and silicon substrate 10 and mitigate residue stress; it can also prevent melt back etching effect between the epitaxy layer 122 and the silicon substrate 10. In a preferred embodiment, the catalyst, indium (In), can be utilized as a catalyst to help the aluminum migration so as to improve the quality and flatness of the aluminum contained nitride buffer layer 121. Hence, the growth quality of the nitride epitaxy layer can be further improved.

According to above-mentioned description, for the same reason, the deposited semiconductor layer 12 comprises at least a III-V compound layer, and the III-V compound layer is deposited on the buffer layer. In one embodiment, the III-V compound layer is a Group III nitride layer. According to another embodiment, the III-V compound layer can be a concentration gradient layer. For example, if the III-V compound layer is an aluminum gallium nitride (AlGaN) layer or a gallium nitride(GaN) layer, the concentration of gallium(Ga) may decrease or increase from the top to the bottom of the III-V compound layer because of atomic diffusion. According to another embodiment, the III-V compound layer may have a superlattice structure. For example, the superlattice structure can comprise at least one of gallium nitride (GaN), aluminum nitride (AlN), and aluminum gallium nitride (AlGaN) stacked together. In another embodiment, the semiconductor layers comprise an epitaxy layer and the epitaxy layer is depositing on the III-V compound layer.

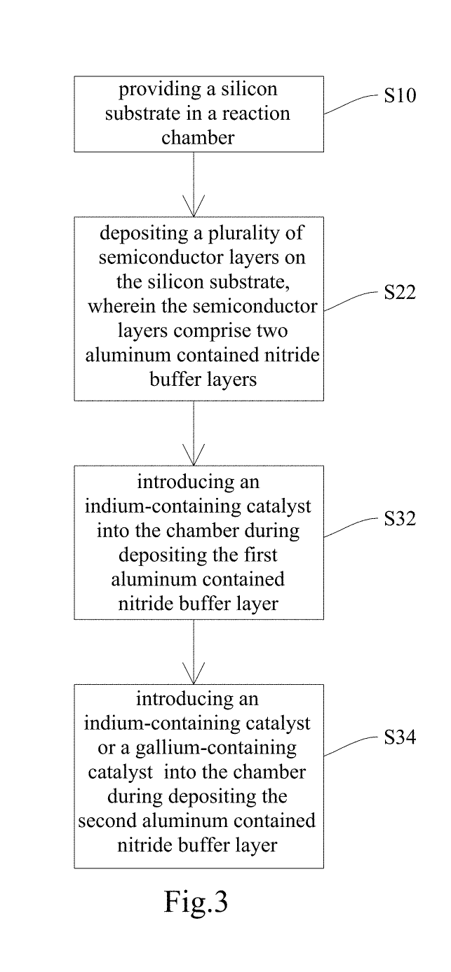

In yet another embodiment, referring to FIG. 3, the semiconductor layer comprises two aluminum contained nitride buffer layers (step S22), wherein a first aluminum contained nitride buffer layer (the first buffer layer) is deposited on the silicon substrate and a second aluminum contained nitride buffer layer (the second buffer layer) is deposited on the first aluminum contained nitride buffer layer; the indium-containing catalyst is introduced into the chamber to enhance migration of aluminum in the aluminum contained nitride layer during depositing the first aluminum contained nitride buffer layer (step S32); and the indium-containing catalyst or a gallium-containing catalyst is introduced into the chamber to enhance migration of aluminum in the second aluminum contained nitride layer during depositing the second aluminum contained nitride buffer layer (step S34). In the embodiment, the first buffer layer and the second buffer layer can be deposited by MOVCD or other appropriate method.

The first buffer layer and the second buffer layer both can comprise but not limited to aluminum nitride (AlN) compounds and are arranged between nitride epitaxy layer and the silicon substrate. Indium-containing catalyst is used to enhance migration of aluminum when growing the first buffer layer and the second buffer layer; higher mobility of aluminum facilitates crystal growth of buffer layers including AlN compound so that process temperature can be lowered. In other words, indium is a surfactant to enhance migration of aluminum. Conventionally, high-quality aluminum nitride (AlN) buffer layers are used to growing in high temperature. However, the equipment which is designed for growing GaN (or other III-V compound layer) cannot reach such high temperature. Extra equipment and process must be developed to overcome the problem. As a result, it leads to more costs and makes the fabrication process more complicated. In the present invention, the first buffer layer and the second buffer layer of the semiconductor multilayer structure 1 can be deposited at lower temperature as well as gallium nitride (GaN) or other Group III nitride layer can be. In addition, the growth temperature of the first buffer layer and the second buffer layer can be either the same or different. In one embodiment, the first buffer layer is deposited on the silicon substrate at a first temperature which ranges from 1000 to 1080 centigrade degrees; and the second buffer layer is deposited on the first buffer layer at a second temperature which ranges from 1000 to 1080 centigrade degrees. It means only one type of equipment or system is needed. Hence, process is simplified and extra costs and energy can be saved.

Referring to FIG. 2, in the embodiment, a semiconductor multilayer structure 1 comprising a silicon substrate 10, and a plurality of semiconductor layers 12, wherein the semiconductor layer 12 comprises an aluminum contained nitride layer (the buffer layer 121) and an epitaxy layer 122. The buffer layer 121, which is formed by introducing an indium-containing catalyst to enhance migration of aluminum in the buffer layer 121, is arranged on the silicon substrate 10. In one embodiment, only a few indiums can be still remained in the buffer layer 121 after the fabrication process is finished. The epitaxial layer 122, such as a nitride epitaxial layer, is arranged on the buffer layer 121, wherein the epitaxy layer 122 comprises but not limited to a gallium nitride (GaN) epitaxial layer, an aluminum gallium nitride (AlGaN) epitaxial layer or an aluminum nitride (AlN) epitaxial layer.

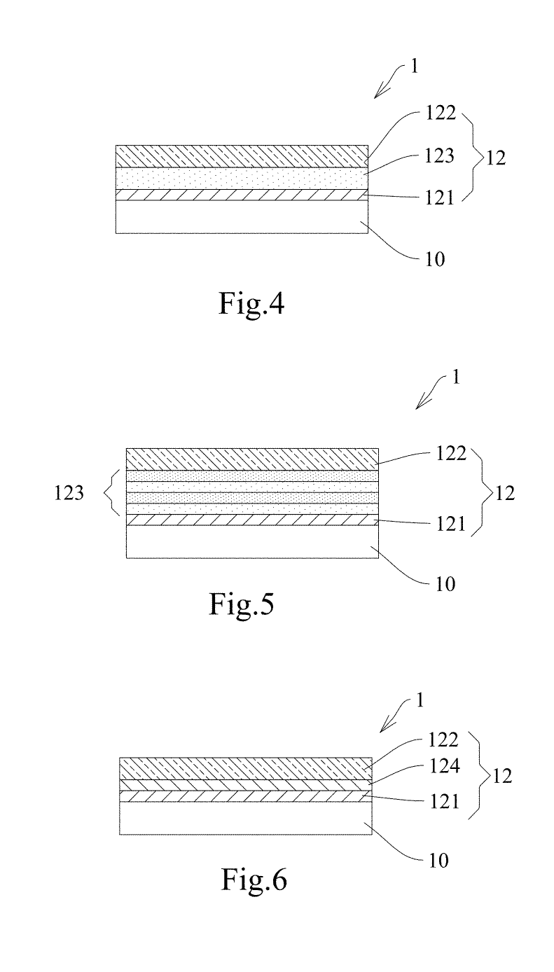

In another embodiment, after growing the buffer layer, as shown in FIG. 4, a III-V compound layer 123 can be deposited on the buffer layer 121 (between the buffer layer 121 and the epitaxy layer 122). The III-V compound layer 123 also can be a buffer layer between the buffer layer 121 and the epitaxial layer 122. In one embodiment, the III-V compound layer 123 is a Group III nitride layer.

According to another embodiment, the III-V compound layer 123 can be a concentration gradient layer. For example, if the III-V compound layer is an aluminum gallium nitride (AlGaN) layer or a gallium nitride (GaN) layer, concentration of gallium (Ga) may decrease or increase from the top to the bottom of the III-V compound layer because of atomic diffusion.

According to another embodiment, referring to FIG. 5, the III-V compound layer 123 has a superlattice structure. Superlattice has a periodic structure (2D or 3D) of layers of two (or more) materials. Semiconductor multilayers with superlattice structure have quantum properties, which can be applied to electronic devices, optical devices or acoustics devices. For example, the superlattice structure can be composed of at least one of gallium nitride (GaN), aluminum nitride (AlN), and aluminum gallium nitride (AlGaN). It should be understood that the superlattice structure as shown in FIG. 5 is presented for the purpose of illustration and description, and should not be used to limit the present invention.

In one embodiment, as illustrated in FIG. 6, the semiconductor layer 12 comprises two aluminum contained nitride buffer layers (buffer layers); a first aluminum contained nitride buffer layers depositing on the silicon substrate 10 is a first buffer layer 121; a second aluminum contained nitride buffer layers depositing on the first buffer layer 121 is a second buffer layer 124; the indium-containing catalyst is introduced into the chamber to enhance migration of aluminum in the first buffer layer during depositing the first buffer layer; and the indium-containing catalyst or a gallium-containing catalyst is utilized to enhance migration of aluminum in the second buffer layer 124 during depositing the second buffer layer , and wherein the second buffer layer 124 comprises but limited to aluminum nitride (AlN) compounds. Herein, indium and/or gallium may still remain in the second buffer layer 124 after the fabrication process is finished so that the second buffer layer 124 may comprise indium, gallium, or combination thereof.

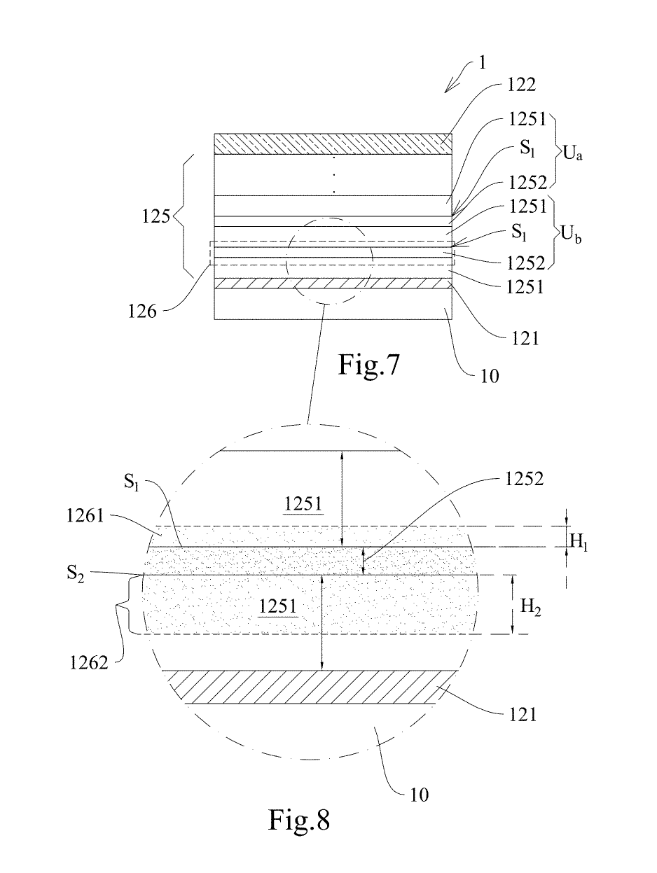

In another embodiment, as illustrated in FIG. 7, the III-V compound layer 123 (as shown in FIG. 5) is a superlattice layer 125. Referring to FIG. 7, the semiconductor multilayer structure 1 comprises a silicon substrate 10 and a plurality of semiconductor layers, wherein the semiconductor layers comprises a buffer layer 121, a superlattice layer 125, a diffusion layer 126, and an epitaxial layer 122. As shown in FIG. 7, the buffer layer 121 is deposited on the silicon substrate 10, and the buffer layer 121 is an aluminum contained nitride buffer layer. The superlattice layer 125 is deposited on the buffer layer 121, wherein the superlattice layer 125 comprises at least a gallium nitride layer 1251 and at least an aluminum nitride layer 1252 stacked together in order. The diffusion layer 126 is formed between the aluminum nitride layer 1252 and the gallium nitride layer 1251, wherein the diffusion layer 126 is an aluminum gallium nitride layer (AlGaN). The epitaxy layer 122 is deposited on the superlattice layer 125. In one embodiment, Al composition of the diffusion layer 126 is greater than Al composition of the gallium nitride layer 1251 and is smaller than Al compositions of the aluminum nitride layer 1252.

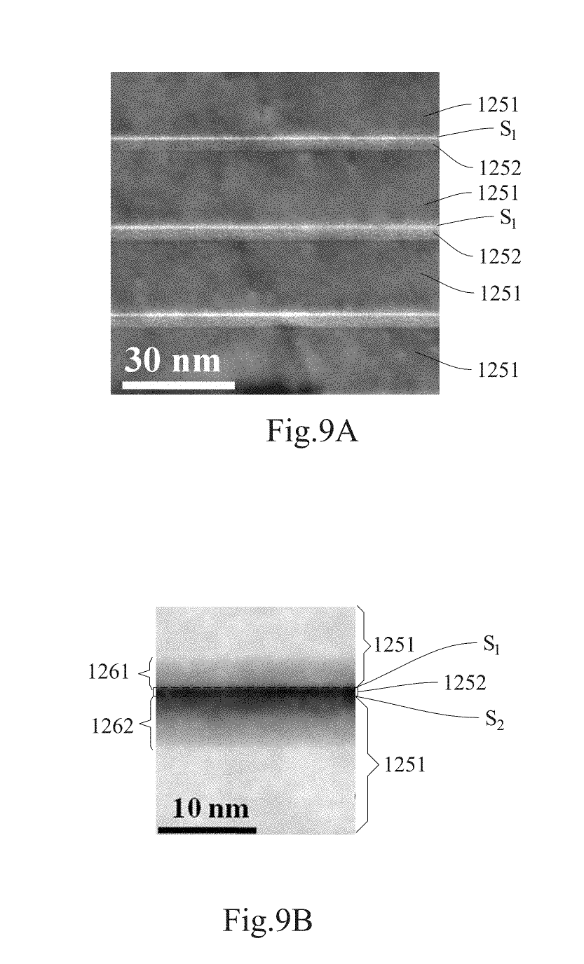

Continuing the above description, referring to FIGS. 7, 8, 9A and 9B, which FIG. 8 is a partially-enlarged diagram of FIG. 7; and FIG. 9A and 9B are electron microscope images showing different partially enlarged views of the semiconductor multilayer structure of the FIG. 7, the diffusion layer 126 comprises a first diffusion layer 1261 and a second diffusion layer 1262. A first contact surface S₁ is formed between the gallium nitride layer 1251 and the aluminum nitride layer 1252, wherein the gallium nitride layer 1251 is stacked on the aluminum nitride layer 1252, defined as a GaN/AlN unit; in one GaN/AlN unit, the first diffusion layer 1261 is formed on the first contact surface S₁. A second contact surface S₂ is formed between the gallium nitride layer 1251 and the aluminum nitride layer 1252, wherein the aluminum nitride layer 1252 is stacked on the gallium nitride layer 1251, the second diffusion layer 1262 is formed under the second contact surface S₂. The diffusion depth H₁ of the first diffusion layer 1261 is smaller than the diffusion depth H₂ of the second diffusion layer 1262. In one embodiment, owing to the gallium nitride layer 1251 and the aluminum nitride layer 1252 are alternatively stacked on each other, such as a upper GaN/AlN unit Uₐ is stacked on a lower GaN/AlN unit U_{b}, the first diffusion layer 1261 may be formed within the gallium nitride layer 1251 of the upper GaN/AlN unit Uₐ and the second diffusion layer 1262 is formed from the second contact surface S₂ and diffuse through a portion of the gallium nitride layer 1251 of the lower GaN/AlN unit U_{b}. Referring to FIG. 9B, FIG. 9B shows the distribution of atomic numbers in aluminum nitride layer 1252/gallium nitride layer 1251 stacked structure. In the grayscale image, the higher atomic number of aluminum is showing a darker color; and the higher atomic number of gallium is showing a lighter color. Because of a dark-filed image is generated from crystal diffraction, the grayscale shown in FIG. 9B is opposite to that shown in FIG. 9A. As shown in FIG. 9B, the diffusion depth of the first diffusion layer 1261 is smaller than the diffusion depth of the second diffusion layer 1262. In another embodiment, the thickness of the gallium nitride layer 1251 is about 18-28 nm, and the thickness of the aluminum nitride layer 1252 is about 4.68 nm in average. Unlike the present invention, the buffer layer of the prior art is composed of two different AlGaN layers that are alternately stacked and have different aluminum compositions. They are totally different structure. Besides, it is harder to manufacture the structure of the present invention because of the high fabrication complexity of the MN and the GaN.

Other structure or operation principles are described as before and will not be elaborated herein.

In conclusion, according to the semiconductor multilayer structure and fabrication method thereof of the present invention, by utilizing the indium-containing and/or gallium-containing catalyst, the aluminum migration can be enhanced to improve the quality and flatness of the aluminum contained nitride buffer layer, hence the temperature of growing aluminum contained nitride buffer layer can be lowered and thermal defects can also be prevented. Additionally, the costs and energy consumption can further be reduced; and the lattice mismatch between MN and GaN of the superlattice layer can be reduced, and efficiently accumulated can be maintained without causing relaxation.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A semiconductor multilayer structure comprising:
a silicon substrate;
a buffer layer deposited on the silicon substrate, and the buffer layer is an aluminum contained nitride buffer layer;
a superlattice layer deposited on the buffer layer, wherein the superlattice layer comprises at least a gallium nitride layer and at least a aluminum nitride layer stacked together in order, and a diffusion layer formed between the aluminum nitride layer and the gallium nitride layer, wherein the diffusion layer is an aluminum gallium nitride layer; and
an epitaxy layer deposited on the superlattice layer.

2. The semiconductor multilayer structure according to claim 1, wherein a first contact surface is formed between the gallium nitride layer and the aluminum nitride layer where the gallium nitride layer is stacked on the aluminum nitride layer; and a second contact surface is formed between the gallium nitride layer and the aluminum nitride layer, wherein the aluminum nitride layer is stacked on the gallium nitride layer.

3. The semiconductor multilayer structure according to claim 2, wherein the diffusion layer comprises a first diffusion layer and a second diffusion layer; the first diffusion layer is formed on the first contact surface; and the second diffusion layer is formed under the second contact surface.

4. The semiconductor multilayer structure according to claim 3, wherein the first diffusion layer is formed within the gallium nitride layer and the second diffusion layer is formed from the second contact surface and diffuse through a portion of the gallium nitride layer stacked below the aluminum nitride layer.

4. The semiconductor multilayer structure according to claim 3, wherein the diffusion depth of the first diffusion layer is smaller than the diffusion depth of the second diffusion layer.

5. The semiconductor multilayer structure according to claim 1, wherein Al composition of the diffusion layer is greater than Al composition of the gallium nitride layer and is smaller than Al compositions of the aluminum nitride layer.
